(19) United States
(12) Patent Application Publication
(10) Pub. No.: US 2024/0061335 A1
(43) Pub. Date: Feb. 22, 2024

(54) CROSSLINKABLE COMPOUND, COMPOSITION CONTAINING SAME FOR FORMATION OF SOLID ELECTROLYTE, METHOD FOR PREPARATION OF SOLID ELECTROLYTE BY USING SAME, AND ELECTRONIC ELEMENT INCLUDING SAME SOLID ELECTROLYTE

(71) Applicants: UNIST(ULSAN NATIONAL INSTITUTE OF SCIENCE AND TECHNOLOGY), Ulsan (KR); IUCF-HYU (Industry-University Cooperation Foundation Hanyang University), Seoul (KR)

(72) Inventors: Bong Soo KIM, Ulsan (KR); Wanho CHO, Ulsan (KR); Do Hwan KIM, Seoul (KR); Hyukmin KWEON, Gyeonggi-do (KR); Chaeyoung LEE, Seoul (KR); Sangjun PARK, Seoul (KR)

(73) Assignees: UNIST(ULSAN NATIONAL INSTITUTE OF SCIENCE AND TECHNOLOGY), Ulsan (KR); IUCF-HYU (Industry-University Cooperation Foundation Hanyang University), Seoul (KR)

(21) Appl. No.: 18/278,921

(22) PCT Filed: Feb. 3, 2022
(86) PCT No.: PCT/KR2022/001688

§ 371 Date: Aug. 25, 2023

(30) Foreign Application Priority Data
Feb. 26, 2021 (KR) 10-2021-0026435
Dec. 23, 2021 (KR) 10-2021-0186595

(51) Int. Cl. G03F 7/039; C08K 5/28; C08L 75/04; G03F 7/20

(52) U.S. Cl. CPC G03F 7/039; C08K 5/28; C08L 75/04; G03F 7/2037

(57) ABSTRACT

The present disclosure relates to a crosslinkable compound, a composition containing the same for formation of a solid electrolyte, a method of preparing a solid electrolyte by using the composition, a solid electrolyte, and an electronic element including the solid electrolyte.

### TECHNICAL FIELD

The present disclosure relates to a crosslinkable compound, a composition containing the same for formation of a solid electrolyte, a method of preparing a solid electrolyte by using the composition, a solid electrolyte, and an electronic element including the solid electrolyte.

### BACKGROUND ART

‘Skin-like’ electronics that imitate the functions of human skin are in the limelight as next-generation technologies, and thus research on flexible and highly stretchable soft electronics, rather than silicon-based hard electronics, is actively being conducted.

As the fields of electronic skin for smart health monitoring, bioimplantable medical devices, and soft robotics develop based on soft electronics, there is a rapidly increasing technical demand for high-performance ‘skin-like’ electronics with high elasticity, low power consumption and a high degree of integration at the same time.

In the case of previously reported stretchable electronics research, an ion-gel material was developed based on a linear block copolymer rather than an elastomer, enabling stable operation only at an extremely limited tensile rate. In addition, as inkjet printing or a process using surface energy control is performed to realize an ion gel pattern, there are still limitations in terms of process efficiency as well as uniformity and resolution of a pattern. Furthermore, an integrated stretchable transistor array has been reported in which a single elastomer is patterned rather than an ionic material, but a high driving voltage is required, and thus there is a limitation in that such an array is difficult to apply to low-power electronics.

In the case of ionic elastomers, the realization of high-resolution patterns through a well-established photolithography process has been limited due to the flexible mechanical properties of the elastomers used as polymer matrices. As a second-best solution for this limitation, various pattern processing methods such as inkjet printing, spray coating, transfer methods, and the like, have been developed, but due to non-uniformity and resolution limitations of patterns, there are still limitations in implementing integrated low-voltage driven stretchable electronics.

### DISCLOSURE

### Technical Problem

Provided are a crosslinkable compound capable of obtaining a crosslinking reaction product having maintained or improved ionic conductivity by including an ion conduction site, and a composition including the crosslinkable compound for forming a solid electrolyte.

Also, provided are a solid electrolyte having a high-resolution pattern by using the composition, and a method of preparing the solid electrolyte.

Also, provided is a high-quality electronic element using the solid electrolyte, for example, an electronic element having high elasticity, low power consumption, and high degree of integration.

### Technical Solution

According to an aspect, there is provided a crosslinkable compound represented by Formula 1:

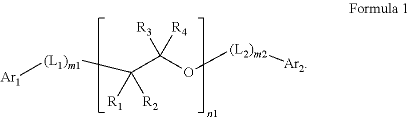

In Formula 1,

L₁ and L₂ may each independently be a single bond, —C═O—, —C, a substituted or unsubstituted C₁-C₃₀ alkylene group, a substituted or unsubstituted C₂-C₃₀ alkenylene group, or a substituted or unsubstituted C₂-C₃₀ alkynylene group,

m1 and m2 may each independently be 0, 1, 2, or 3,

Ar₁ and Ar₂ may each independently be a substituted or unsubstituted C₅-C₆₀ carbocyclic group or a substituted or unsubstituted C₁-C₆₀ heterocyclic group,

Ar₁ and Ar₂ may each independently be substituted with at least one crosslinkable group,

n1 may be an integer from 2 to 300,000,

R₁ to R₄ may each independently be hydrogen, deuterium, —F, —Br, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, —Si(Q₁)(Q₂)(Q₃), a substituted or unsubstituted C₅-C₆₀ carbocyclic group, or a substituted or unsubstituted C₁-C₆₀ heterocyclic group,

at least one of the substituted C₁-C₃₀ alkylene group, the substituted C₂-C₃₀ alkenylene group, the substituted C₂-C₃₀ alkynylene group, the substituted C₅-C₆₀ carbocyclic group, the substituted C₁-C₆₀ heterocyclic group, the substituted C₁-C₃₀ alkyl group, the substituted C₂-C₃₀ alkenyl group, the substituted C₂-C₃₀ alkynyl group, the substituted C₁-C₃₀ alkoxy group, and the substituted C₁-C₃₀ alkylthio group may be substituted with deuterium, —F, —Br, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, or —Si(Q₁₁)(Q₁₂)(Q₁₃), and

Q₁₁ to Q₁₃ may each independently be hydrogen, deuterium, —F, —Br, a hydroxyl group, a cyano group, a C₁-C₃₀ alkyl group, a C₂-C₃₀ alkenyl group, a C₂-C₃o alkynyl group, a C₁-C₃₀ alkoxy group, or a C₁-C₃₀ alkylthio group.

According to another aspect, there is provided a composition for forming a solid electrolyte, including an ionic elastomer, an ionic liquid, and a photo-crosslinking agent, wherein the photo-crosslinking agent contains the crosslinkable compound.

According to another aspect, there is provided a method of preparing a solid electrolyte, the method including exposing the composition for forming a solid electrolyte to ultraviolet (UV) rays.

According to another aspect, there is provided a solid electrolyte prepared by using the composition for forming a solid electrolyte.

According to another aspect, there is provided an electronic element including the solid electrolyte.

### Advantageous Effects

The crosslinkable compound according to an embodiment may obtain a crosslinking reaction product having maintained or improved ionic conductivity by including an ion conduction site.

Also, a solid electrolyte having a high-resolution ion-gel pattern formed therein may be prepared through a simple photo-patterning process by using the composition for forming a solid electrolyte including an ionic elastomer, an ionic liquid, and the crosslinkable compound.

Also, the solid electrolyte may have excellent electrochemical characteristics and flexibility as well as stretchable characteristics, and thus the electronic element including the same may have high-quality characteristics such as high elasticity, low power consumption, and high degree of integration.

Also, the solid electrolyte can be applied to bio-implantable/attachable medical electronic skin, soft robotics, and displays, which are high value-added industries in the field of next-generation electronic skin.

### DESCRIPTION OF DRAWINGS

FIG. 1 is a schematic view of a solid electrolyte according to an embodiment of the present disclosure.

FIG. 2 is a view illustrating a preparation process for a solid electrolyte according to an embodiment of the present disclosure.

FIG. 3 is a microscope view confirming whether a pattern was formed in a solid electrolyte according to an embodiment of the present disclosure.

FIGS. 4A and 4B are views showing electrochemical characteristics of a capacitor device prepared by using a solid electrolyte according to an embodiment of the present disclosure.

FIG. 5 shows the results of impedance analysis of a solid electrolyte according to Examples and Comparative Examples of the present disclosure.

FIG. 6 shows the results of electrical characteristics of a transistor prepared by using a solid electrolyte according to an embodiment of the present disclosure.

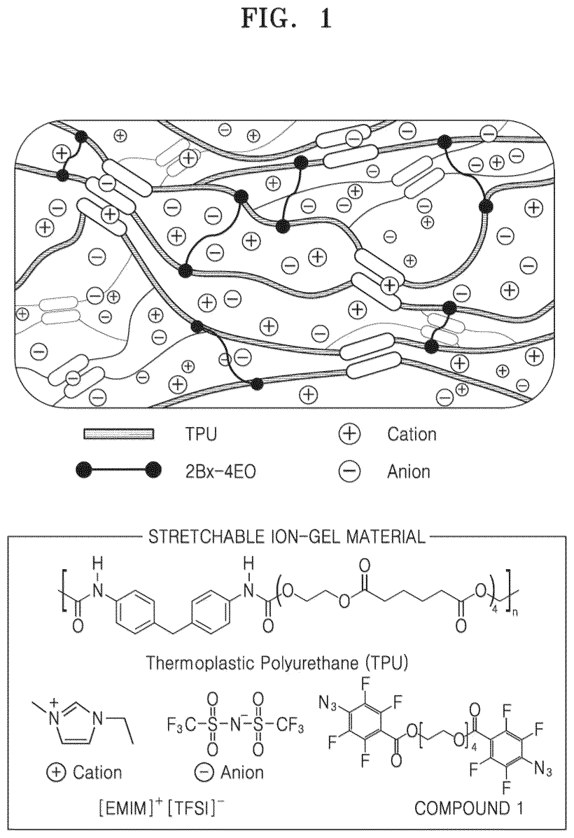

### BEST MODE

Hereinafter, the present disclosure will be described in more detail.

In the present specification, it is to be understood that the terms such as “including,” “having,” and “comprising” are intended to indicate the existence of the features or components disclosed in the specification, and are not intended to preclude the possibility that one or more other features or components may exist or may be added.

In the present specification, when various components such as layers, films, etc. are said to be “on” another component, this may include not only a case in which other components are “immediately on” the layers, films, etc., but also a case in which other components may be placed therebetween.

[Crosslinkable Compound]

A crosslinkable compound according to an embodiment may be represented by Formula 1:

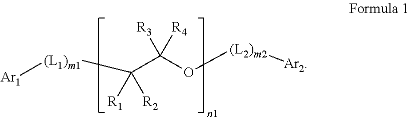

In Formula 1,

L₁ and L₂ may each independently be a single bond, —C═O—, —C(═O)O—, a substituted or unsubstituted C₁-C₃₀ alkylene group, a substituted or unsubstituted C₂-C₃₀ alkenylene group, or a substituted or unsubstituted C₂-C₃₀ alkynylene group,

m1 and m2 may each independently be 0, 1, 2, or 3,

Ar₁ and Ar₂ may each independently be a substituted or unsubstituted C₅-C₆₀ carbocyclic group or a substituted or unsubstituted C₁-C₆₀ heterocyclic group,

Ar₁ and Ar₂ may each independently be substituted with at least one crosslinkable group,

R₁ to R₄ may each independently be hydrogen, deuterium, —F, —Cl, —Br, —I, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted alkylthio group, —Si(Q₁)(Q₂)(Q₃), a substituted or unsubstituted C₅-C₆₀ carbocyclic group, or a substituted or unsubstituted C₁-C₆₀ heterocyclic group,

n1 may be an integer from 2 to 300,000,

at least one of the substituted C₁-C₃₀ alkylene group, the substituted C₂-C₃₀ alkenylene group, the substituted C₂-C₃₀ alkynylene group, the substituted C₅-C₆₀ carbocyclic group, the substituted C₁-C₆₀ heterocyclic group, the substituted C₁-C₃₀ alkyl group, the substituted C₂-C₃₀ alkenyl group, and the substituted C₂-C₃₀ alkynyl group may be substituted with deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃₀ alkoxy group, a C₁-C₃₀ alkylthio group, or —Si(Q₁)(Q₂)(Q₃), and

Q₁₁ to Q₁₃ may each independently be hydrogen, deuterium, —F, —Cl, —Br, —I, a hydroxyl group, a cyano group, a C₁-C₃₀ alkyl group, a C₂-C₃₀ alkenyl group, a C₂-C₃o alkynyl group, a C₁-C₃₀ alkoxy group, or a C₁-C₃₀ alkylthio group.

In an embodiment, L₁ and L₂ may each independently be a single bond, —C═O—, or a methylene group.

In an embodiment, m1 and m2 may each independently be 1 or 2.

In an embodiment, Ar₁ and Ar₂ may each independently be a substituted or unsubstituted phenyl group, and may each independently be substituted with at least one crosslinkable group.

In an embodiment, n1 may be an integer from 2 to 100,000.

In an embodiment, n1 may be an integer from 2 to 50,000.

In an embodiment, n1 may be an integer from 2 to 10,000.

In an embodiment, n1 may be an integer from 2 to 5,000.

In an embodiment, n1 may be an integer from 2 to 1,000.

In an embodiment, n1 may be an integer from 2 to 500.

In an embodiment, n1 may be an integer from 2 to 200.

In an embodiment, n1 may be an integer from 2 to 100.

In an embodiment, n1 may be an integer from 2 to 24.

In an embodiment, n1 may be an integer from 2 to 20.

In an embodiment, n1 may be an integer from 4 to 16.

In an embodiment, the crosslinkable group may be an azide group (—N₃), a sulfur-containing group, or an unsaturated double bond-containing group.

In an embodiment, the crosslinkable group may be an azide group.

In an embodiment, the crosslinkable compound may be represented by Formula 2:

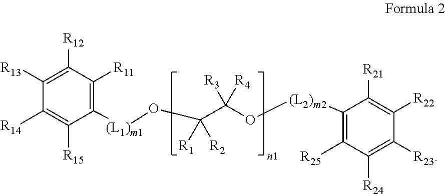

In Formula 2,

L₁, L₂, m1, m2, n1, and R₁ to R₄ are referred to those described herein, R₁₁ to R₁₅ and R₂₁ to R₂₅ may each independently be a crosslinkable group, hydrogen, deuterium, —F, —Cl, —Br, —I, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, —Si(Q₁)(Q₂)(Q₃), a substituted or unsubstituted C₅-C₆₀ carbocyclic group, or a substituted or unsubstituted C₁-C₆₀ heterocyclic group,

at least one of R₁₁ to R₁₅ may be a crosslinkable group, and

at least one of R₂₁ to R₂₅ may be a crosslinkable group.

In an embodiment, one of R₁₁ to R₁₅ may be an azide group, and the others may each be —F.

In an embodiment, one of R₂₁ to R₂₅ may be an azide group, and the others may each be —F.

In an embodiment, the crosslinkable compound may be represented by Formula 3:

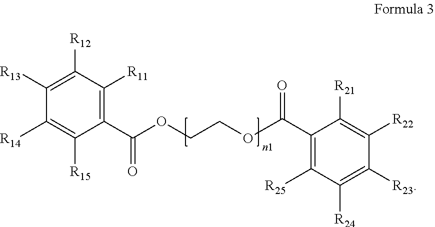

In Formula 3,

n1, R₁₁ to R₁₅, and R₂₁ to R₂₅ may each be the same as described herein.

In an embodiment, the crosslinkable compound may be selected from Compounds 1 to 5:

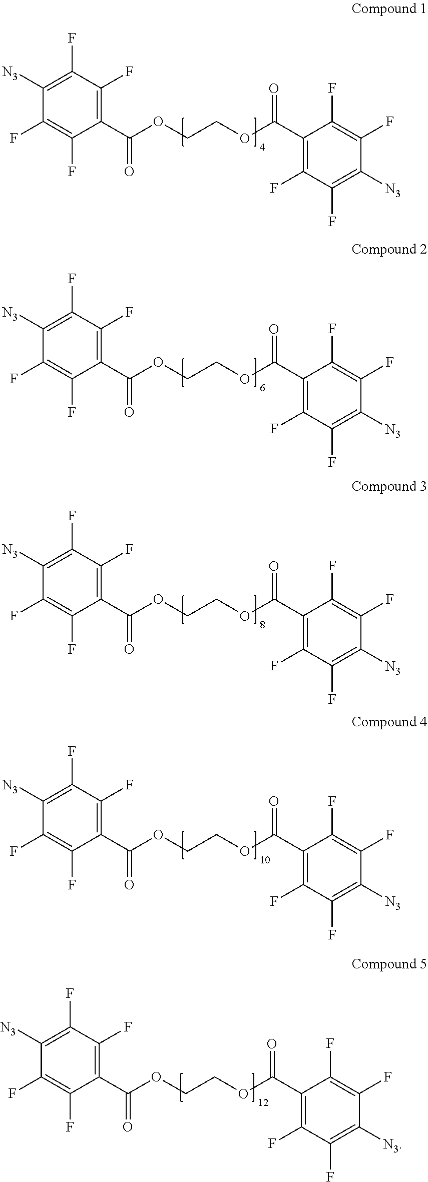

The crosslinkable compound include a repeating unit represented by Formula E while satisfying the structure of Formula 1:

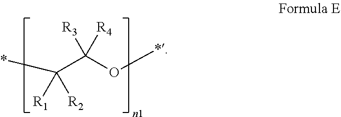

In Formula E,

R₁ to R₄ and n1 may each be the same as described herein, and

* and *′ indicate a binding site to a neighboring atom.

The repeating unit represented by Formula E included in the crosslinkable compound may provide an ion conduction site for an adjacent salt, and thus, when a crosslinking reaction using the crosslinkable compound occurs, the ionic conductivity of a product may be maintained or improved. Also, by controlling the number of the repeating units, the ionic conductivity of the crosslinking reaction product may be controlled.

[Composition for Forming Solid Electrolyte]

Another aspect provides a composition for forming a solid electrolyte, the composition including an ionic elastomer, an ionic liquid, and a photo-crosslinking agent.

In an embodiment, the photo-crosslinking agent may include the aforementioned crosslinkable compound represented by Formula 1.

When the photo-crosslinking agent is exposed to ultraviolet rays, the crosslinkable group may be activated so that a chemical crosslink between the adjacent ionic elastomer and the photo-crosslinking agent may be formed. For example, the crosslinkable group may be an azide group (—N₃), which can be activated as nitrene (-1N) to form a chemical crosslink with an alkyl chain of the adjacent ionic elastomer.

In an embodiment, the composition for forming a solid electrolyte may include an ionic elastomer.

Since the ionic elastomer has flexible mechanical properties, high elasticity may be provided when forming a solid electrolyte, thereby forming a stretchable solid electrolyte.

In an embodiment, the ionic elastomer may be a polyurethane polymer.

In an embodiment, the ionic elastomer may be a thermoplastic polyurethane (TPU) polymer.

In an embodiment, the TPU polymer may include a repeating unit represented by Formula 10:

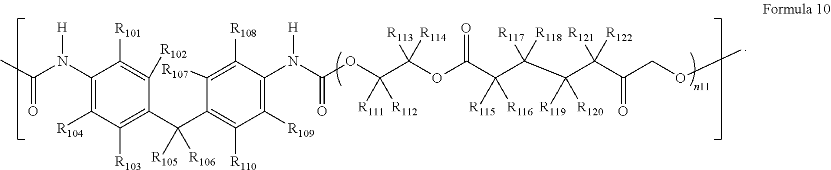

In Formula 10,

n11 may be an integer from 1 to 5,000, and

R₁₀₁ to R₁₂₂ may each independently be hydrogen, deuterium, —F, —Cl, —Br, —I, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, —Si(Q₁)(Q₂)(Q₃), a substituted or unsubstituted C₅-C₆₀ carbocyclic group, or a substituted or unsubstituted C₁-C₆₀ heterocyclic group.

In an embodiment, n11 may be an integer from 1 to 1,000.

In an embodiment, n11 may be an integer from 1 to 500.

In an embodiment, n11 may be an integer from 1 to 200.

In an embodiment, n11 may be an integer from 1 to 100.

In an embodiment, n11 may be an integer from 1 to 50.

In an embodiment, n11 may be an integer from 1 to 20.

In an embodiment, n11 may be an integer from 1 to 10.

In an embodiment, the TPU polymer may include n21 repeating units represented by Formula 10, wherein n21 may be any integer. For example, n21 may be an integer from 1 to 500,000. In one or more embodiments, n21 may be an integer from 1 to 100,000, an integer from 1 to 50,000, or an integer from 1 to 10,000.

In an embodiment, the TPU polymer may include a repeating unit represented by Formula P1:

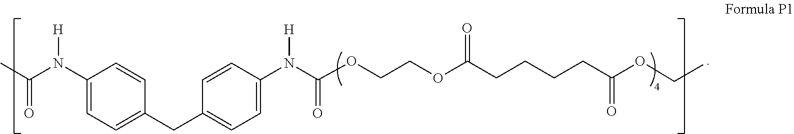

In an embodiment, the TPU polymer may include n21 repeating units represented by Formula 10, wherein n21 may be the same as described herein.

In an embodiment, the ionic liquid may be a nitrogen-containing ionic liquid, a phosphorus (P)-containing ionic liquid, or any combination thereof.

In an embodiment, the ionic liquid may contain a cation and an anion,

the cation may be an ammonium ion, an imidazolium ion, a piperidinium ion, a pyrrolidinium ion, a phosphonium ion, or any combination thereof, and

the anion may be a halogen ion, an acetate ion (CH₃CO₂⁻), a nitrate ion (NO₃⁻), a tetrafluoroborate ion (BF₄⁻), a hexafluorophosphate ion (PF₆⁻), a trifluoromethane sulfonate ion (Tf⁻), a bis((trifluoromethyl)sulfonyl)imide ion (TFSI⁻), or any combination thereof:

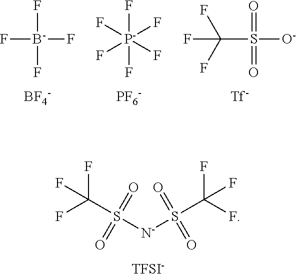

In an embodiment, the ionic liquid may be [EMIM][TFS1](1-ethyl-3-methylimidazolium bis(trifluoromethylsulfonyl)imide).

The photo-crosslinking agent may include the aforementioned crosslinkable compound represented by Formula 1.

In an embodiment, the weight ratio of the photo-crosslinking agent to the ionic elastomer may be 1:0.01 to 1:0.1.

When weight ratio of the photo-crosslinking agent to the ionic elastomer is satisfied within the range above, a solid electrolyte having excellent ionic conductivity and elasticity through use of the composition for forming a solid electrolyte and having a high-resolution pattern formed through a simple photo-patterning process may be obtained. Accordingly, the efficiency and pattern uniformity during the process may be increased.

In an embodiment, the composition for forming a solid electrolyte may further include a solvent. For use as the solvent, a substance capable of dissolving the ionic elastomer may be used.

In an embodiment, the solvent may be a polar solvent.

In an embodiment, the solvent may be dimethylformamide (DMF), tetrahydrofuran (THF), or acetone.

[Method of Preparing Solid Electrolyte and Solid Electrolyte Formed Thereby]

Another aspect provides a method of preparing a solid electrolyte by using the composition for forming a solid electrolyte.

In an embodiment, the method of preparing a solid electrolyte may include exposing the composition for forming a solid electrolyte to ultraviolet (UV) rays.

In an embodiment, the method of preparing a solid electrolyte may further include forming a pattern by developing the UV-exposed composition for forming a solid electrolyte.

The forming of the pattern is a process of removing a portion that is not crosslinked by UV exposure through a developing solvent, and through this process, a solid electrolyte having a high-resolution pattern may be obtained.

For use as the developing solvent, a substance capable of dissolving a portion that is not crosslinked by UV exposure may be used.

In an embodiment, the developing solvent may be DMF.

In the case of preparing a solid electrolyte by using the composition for forming a solid electrolyte, a high-resolution patterned solid electrolyte can be directly obtained through a simple photolithography process rather than through a printing and transcription method, thereby providing remarkable superiority in terms of process efficiency and pattern uniformity.

Also, another aspect provides a solid electrolyte prepared by using the composition for forming a solid electrolyte.

The solid electrolyte may contain a product of a crosslinking reaction between the ionic elastomer and the photo-crosslinking agent, and an ionic liquid. Also, the solid electrolyte may further include the ionic elastomer and/or the photo-crosslinking agent that has not undergone a crosslinking reaction.

According to the method of preparing the solid electrolyte, a solid electrolyte having excellent ionic conductivity and elasticity and having a high-resolution pattern formed through a simple photo-patterning process may be obtained. Also, the efficiency and pattern uniformity during the process may be increased.

In an embodiment, the solid electrolyte may be a stretchable solid electrolyte.

In an embodiment, the solid electrolyte may include an ionic pattern.

In an embodiment, the width of the ionic pattern may be 1 μm to 10 μm, or may be 10 μm or greater.

In an embodiment, the width of the ionic pattern may be 3 μm to 7 μm, for example 3 μm to 5 μm.

[Electronic Element]

Another aspect provides an electronic element including the solid electrolyte.

In an embodiment, the electronic element may be any one of an organic solar cell (OSC), an organic thin-film transistor (OTFT), an organic light-emitting diode (OLED), an organic photodiode sensor (OPD), a perovskite solar cell, a perovskite light-emitting diode, and a thermoelectric device.

In an embodiment, the electronic element may be an organic thin-film transistor.

For example, the electronic element may be an organic thin-film transistor having a bottom-gate/bottom-contact (BGBC) structure, and such an organic thin-film transistor may include: a substrate; a gate; an organic semiconductor thin film on the gate insulating film; and a source electrode and a drain electrode on the organic semiconductor thin film.

In an embodiment, for example, the electronic element may be an organic thin-film transistor having a top-gate/bottom-contact (TGBC) structure, and such an organic thin-film transistor may include: a substrate; a source electrode and a drain electrode on the substrate; an organic semiconductor thin film arranged on the source electrode and the drain electrode and including an organic semiconductor compound; a gate insulating film on the organic semiconductor thin film; and a gate electrode on the gate insulating film.

The source electrode, the drain electrode, and the gate electrode may each have a single-layer structure consisting of a single layer or a multi-layer structure consisting of a plurality of layers, and the organic thin-film transistor may include metals (e.g., Au, Al, Ag, Mg, Ca, Yb, Cs—ITO, an alloy thereof, etc.) or metal particles commonly used in the art, a carbon-based material (e.g., a nanotube, graphene, etc.), or a conductive polymer material (e.g., PEDOT:PSS, PANI, etc.).

In an embodiment, the source electrode and the drain electrode may include gold (Au).

In an embodiment, the gate electrode may include silver (Ag), for example, a silver nanowire (AgNW).

The gate insulating film may have a single-layer structure consisting of a single layer or a multi-layer structure consisting of a plurality of layers, and the organic thin-film transistor may use an insulator having high dielectric permittivity and commonly used in the art.

For example, the gate insulating film may include: an organic material, such as a polyvinyl alcohol-based compound, a polyimide-based compound, a polyacryl-based compound, a polystyrene-based compound, benzocyclobutane (BCB), and the like; an inorganic material, such as silicon nitride (SiNₓ), aluminum oxide (Al₂O₃), silicon oxide (SiO₂), and the like; or a combination thereof. In one or more embodiments, the gate insulating film may include various ionic liquids and an insulating polymer.

In an embodiment, the solid electrolyte may be used as an insulator of the gate insulating film.

When the organic thin-film transistor includes the solid electrolyte as an insulator of the gate insulating film, an organic thin-film transistor having high elasticity, low power consumption, and high degree of integration that are ensured simultaneously.

In an embodiment, the electronic element may be a stretchable electronic element.

In the present specification, the C₅-C₆₀ carbocyclic group refers to a monocyclic group or a polycyclic group, each consisting of carbon only as a ring-forming atom and having 5 to 60 carbon atoms. The C₅-C₆₀ carbocyclic group may be an aromatic carbocyclic group or a non-aromatic carbocyclic group. The C₅-C₆₀ carbocyclic group may be a ring such as benzene, a monovalent group such as a phenyl group, or a divalent group such as a phenylene group. In one or more embodiments, depending on the number of substituents linked to the C₅-C₆₀ carbocyclic group, the C₅-C₆₀ carbocyclic group may be variously modified, such as being a trivalent group or a tetravalent group.

In the present specification, the C₁-C₆₀ heterocyclic group refers to a group having the same structure as the C₅-C₆₀ carbocyclic group and including, as a ring-forming atom, at least one heteroatom selected from N, O, Si, P, and S, in addition to carbon (wherein the number of carbon atoms may be 1 to 60).

In the present specification, the C₁-C₃₀ alkyl group refers to a linear or branched aliphatic hydrocarbon group having 1 to 30 carbon atoms, and specific examples thereof include a methyl group, an ethyl group, a propyl group, an isobutyl group, a sec-butyl group, a ter-butyl group, a pentyl group, an iso-amyl group, a hexyl group, a heptyl group, an n-octyl group, a 2-ethylhexyl group, and the like.

In the present specification, the C₂-C₃₀ alkenyl group refers to a hydrocarbon group including at least one carbon-carbon double bond in the middle or at the terminus of the C₂-C₃₀ alkyl group, and specific examples thereof include an ethenyl group, a propenyl group, a butenyl group, and the like.

In the present specification, the C₂-C₃₀ alkynyl group refers to a hydrocarbon group including at least one carbon-carbon triple bond in the middle or at the terminus of the C₂-C₃₀ alkyl group, and specific examples thereof include an ethynyl group, a propynyl group, and the like.

In the present specification, the C₁-C₃₀ alkoxy group refers to a monovalent group represented by —OA₁₀₁ (wherein A₁₀₁ is the C₁-C₃₀ alkyl group), and specific examples thereof include a methoxy group, an ethoxy group, an isopropyloxy group, and the like.

In the present specification, the C₁-C₃₀ alkylthio group refers to a monovalent group represented by —SA₁₀₁ (wherein A₁₀₁ is the C₁-C₃₀ alkyl group), and specific examples thereof include a methylthio group, an ethylthio group, an isopropylthio group, and the like.

In the present specification, * and *′, unless defined otherwise, each refer to a binding site to a neighboring atom in a corresponding formula.

Mode for Invention

Hereinafter, an organic semiconductor compound according to embodiments will be described in detail with reference to Synthesis Examples. The expression “B was used instead of A” as used in describing Synthesis Examples below refers that an identical molar equivalent of B was used in place of A, unless otherwise specified.

Hereinafter, an organic semiconductor compound according to embodiments will be described in detail with reference to Synthesis Examples and Examples. Synthesis Examples and Examples below are for explaining the present disclosure in more detail, but the scope of the present disclosure is not limited to these Synthesis Examples and Examples.

### Synthesis Example 1: Synthesis of Compound 1

(1) Synthesis of Intermediate 1(1)

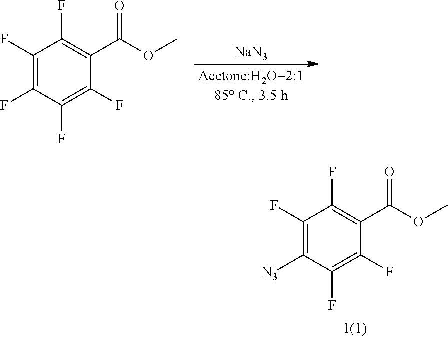 [SMILES: COC(=O)c1c(F)c(F)c(F)c(F)c1F ; COC(=O)c1c(F)c(F)c(N=[N+]=[N-])c(F)c1F ; "NaN3"]

A dried magnetic bar placed in a 500 ml round-bottom flask was prepared. After the round-bottom flask was vacuum-dried while heating with a torch, the flask was filled with argon. Methylpentafluorobenzoate (24.9 g, 110.36 mmol) and sodium azide (9.3 g, 143.47 mmol) were added to the flask and vacuum-dried for 1 hour. Distilled water (81.1 mL) and acetone (162.2 mL) were added to the flask and stirred on a hot plate at 85° C. for 3.5 hours. After the reaction was terminated by using distilled water, an extraction process was performed on the mixture three times by using an extraction funnel and chloroform. After removing moisture from the organic layer obtained from the extraction process by using anhydrous MgSO₄, the organic solvent was removed by using a rotary evaporator. Accordingly, the organic material thus obtained was filtered through silica gel and chloroform and dried by using a rotary evaporator, so as to obtain Intermediate 1(1) as a white solid product. The product weighed 26.4 g, and a yield thereof was analyzed to be 96%.

(2) Synthesis of Intermediate 1(2)

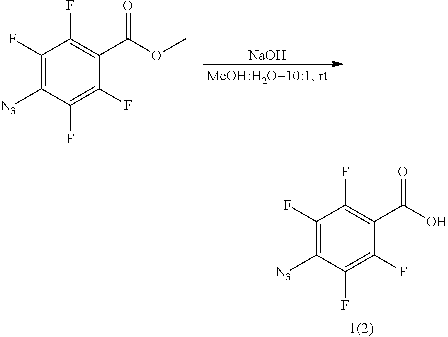 [SMILES: COC(=O)c1c(F)c(F)c(N=[N+]=[N-])c(F)c1F ; "NaOH" ; [N-]=[N+]=Nc1c(F)c(F)c(C(=O)O)c(F)c1F]

A dried magnetic bar placed in a 500 ml round-bottom flask was prepared. After the round-bottom flask was vacuum-dried while heating with a torch, the flask was filled with argon. Methyl-4-azido-2,3,5,6-tetrafluorobenzoate (11.8 g, 47.28 mmol) was added to the flask and vacuum-dried for 1 hour. Methanol (MeOH) (157.6 mL) and distilled water (15.8 mL) were added to the flask, and sodium hydroxide (101.57 mmol) dissolved in distilled water was added thereto. After a reaction was allowed at room temperature for 5 hours, an extraction process was performed on the mixture three times by using an extraction funnel and chloroform. After removing moisture from the organic layer obtained from the extraction process by using anhydrous MgSO₄, the organic solvent was removed by using a rotary evaporator. The organic material thus obtained was recrystallized by using chloroform and MeOH, and a white solid product was obtained by using a filter paper. The product weighed 10.9 g, and a yield thereof was analyzed to be 98%.

(3) Synthesis of Compound 1

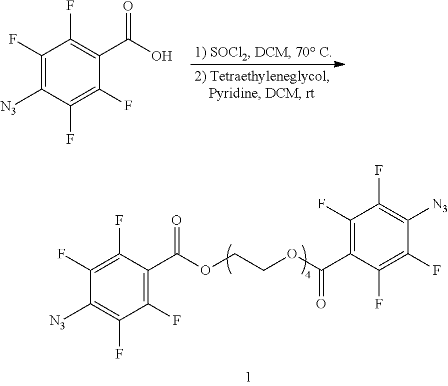

A dried magnetic bar placed in a 100 ml round-bottom flask was prepared. After the round-bottom flask was vacuum-dried while heating with a torch, the flask was filled with argon. 4-azido-2,3,5,6-tetrafluorobenzoic acid (3.9 g, 16.55 mmol) was added to the flask and vacuum-dried for 1 hour. Thionyl chloride (SOCl₂) (1.4 mL, 19.10 mmol) and anhydrous dichloromethane (DCM) (10 mL) were sequentially added to the flask to prepare a mixture. The mixture was heated to 70° C. and stirred for 18 hours. After the mixture was cooled to room temperature, the organic solvent was removed therefrom by using a rotary evaporator, and then, additionally dried by using a vacuum pump to obtain a product. The product was diluted with anhydrous DCM (10 mL) to prepare a first mixture, which was prepared under an argon atmosphere.

A dried magnetic bar placed in a separate 100 ml round-bottom flask was prepared. After the round-bottom flask was vacuum-dried while heating with a torch, the flask was filled with argon. Tetraethylene glycol (1.2 g, 6.37 mmol), pyridine (1.5 g, 19.10 mmol), and anhydrous DCM (20 mL) were added to the flask and stirred to prepare a mixture. The previously prepared first mixture was added dropwise to the mixture to prepare a second mixture. After the second mixture was stirred at room temperature for 8 hours, distilled water (20 mL) was added thereto to terminate the reaction. An extraction process was performed on the second mixture by using an extraction funnel, distilled water, and dichloromethane (50 mL). After removing moisture from the organic layer obtained from the extraction process which was performed three times by using anhydrous MgSO₄, the organic solvent was removed by using a rotary evaporator. Accordingly, the organic material thus obtained was separated through silica gel column chromatography (ethyl acetate:n-hexane=1:2), so as to obtain a yellow liquid product. The liquid product weighed 3.3 g, and a yield thereof was analyzed to be 83%.

### Synthesis Example 2: Synthesis of Compound 2

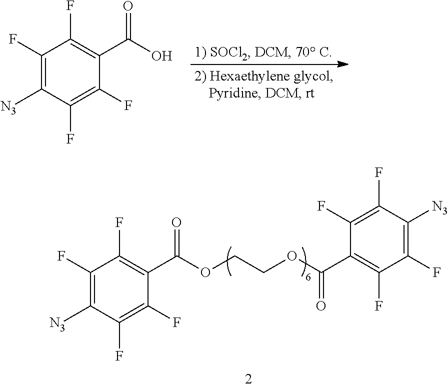

A dried magnetic bar placed in a 100 ml round-bottom flask was prepared. After the round-bottom flask was vacuum-dried while heating with a torch, the flask was filled with argon. 4-azido-2,3,5,6-tetrafluorobenzoic acid (3.7 g, 15.55 mmol) was added to the flask and vacuum-dried for 1 hour. Thionyl chloride (SOCl₂) (1.3 mL, 17.9 mmol) and anhydrous DCM (20 mL) were sequentially added to the flask to prepare a mixture. The mixture was heated to 70° C. and stirred for 18 hours. After the mixture was cooled to room temperature, the organic solvent was removed therefrom by using a rotary evaporator, and then, additionally dried by using a vacuum pump to obtain a product. The product was diluted with anhydrous DCM (10 mL) to prepare a first mixture, which was prepared under an argon atmosphere.

A dried magnetic bar placed in a separate 100 ml round-bottom flask was prepared. After the round-bottom flask was vacuum-dried while heating with a torch, the flask was filled with argon. Hexaethylene glycol (1.7 g, 5.98 mmol), pyridine (1.9 g, 23.93 mmol), and anhydrous DCM (30 mL) were added to the flask and stirred to prepare a mixture. The previously prepared first mixture was added dropwise to the mixture to prepare a second mixture. After the second mixture was stirred at room temperature for 8 hours, distilled water (20 mL) was added thereto to terminate the reaction. An extraction process was performed on the second mixture by using an extraction funnel, distilled water, and dichloromethane (50 mL). After removing moisture from the organic layer obtained from the extraction process which was performed three times by using anhydrous MgSO₄, the organic solvent was removed by using a rotary evaporator. Accordingly, the organic material thus obtained was separated through silica gel column chromatography (ethyl acetate:n-hexane=3:1), so as to obtain a yellow liquid product. The liquid product weighed 2.8 g, and a yield thereof was analyzed to be 65%.

### Synthesis Example 3: Synthesis of Compound 3

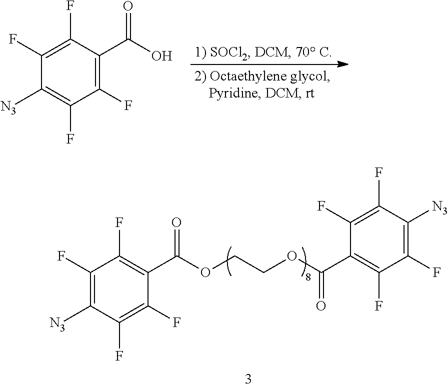

A dried magnetic bar placed in a 100 ml round-bottom flask was prepared. After the round-bottom flask was vacuum-dried while heating with a torch, the flask was filled with argon. 4-azido-2,3,5,6-tetrafluorobenzoic acid (2.8 g, 11.75 mmol) was added to the flask and vacuum-dried for 1 hour. Thionyl chloride (SOCl₂) (1.0 mL, 13.6 mmol) and anhydrous dichloromethane (DCM) (10 mL) were sequentially added to the flask to prepare a mixture. The mixture was heated to 70° C. and stirred for 18 hours. After the mixture was cooled to room temperature, the organic solvent was removed therefrom by using a rotary evaporator, and then, additionally dried by using a vacuum pump to obtain a product. The product was diluted with anhydrous DCM (10 mL) to prepare a first mixture, which was prepared under an argon atmosphere.

A dried magnetic bar placed in a separate 100 ml round-bottom flask was prepared. After the round-bottom flask was vacuum-dried while heating with a torch, the flask was filled with argon. Octaethylene glycol (1.7 g, 4.52 mmol), pyridine (1.4 g, 18.08 mmol), and anhydrous DCM (30 mL) were added to the flask and stirred to prepare a mixture. The previously prepared first mixture was added dropwise to the mixture to prepare a second mixture. After the second mixture was stirred at room temperature for 8 hours, distilled water (20 mL) was added thereto to terminate the reaction. An extraction process was performed on the second mixture by using an extraction funnel, distilled water, and dichloromethane (50 mL). After removing moisture from the organic layer obtained from the extraction process which was performed three times by using anhydrous MgSO₄, the organic solvent was removed by using a rotary evaporator. Accordingly, the organic material thus obtained was separated through silica gel column chromatography (ethyl acetate:n-hexane=9:1), so as to obtain a yellow liquid product. The liquid product weighed 3.0 g, and a yield thereof was analyzed to be 83%.

### Synthesis Example 4: Synthesis of Compound 4

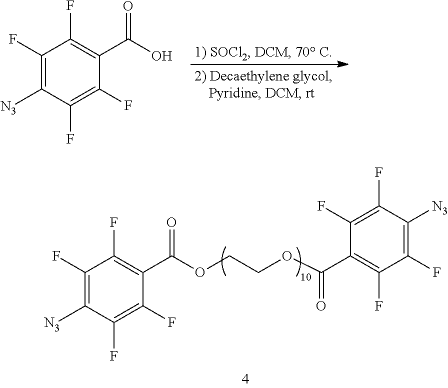

A dried magnetic bar placed in a 50 ml round-bottom flask was prepared. After the round-bottom flask was vacuum-dried while heating with a torch, the flask was filled with argon. 4-azido-2,3,5,6-tetrafluorobenzoic acid (1.4 g, 5.88 mmol) was added to the flask and vacuum-dried for 1 hour. Thionyl chloride (SOCl₂) (0.49 mL, 6.81 mmol) and anhydrous DCM (9 mL) were sequentially added to the flask to prepare a mixture. The mixture was heated to 70 ° C. and stirred for 18 hours. After the mixture was cooled to room temperature, the organic solvent was removed therefrom by using a rotary evaporator, and then, additionally dried by using a vacuum pump to obtain a product. The product was diluted with anhydrous DCM (9 mL) to prepare a first mixture, which was prepared under an argon atmosphere.

A dried magnetic bar placed in a separate 100 ml round-bottom flask was prepared. After the round-bottom flask was vacuum-dried while heating with a torch, the flask was filled with argon. Decaethylene glycol (900.0 mg, 1.96 mmol), pyridine (465.8 mg, 5.89 mmol), and anhydrous DCM (30 mL) were added to the flask and stirred to prepare a mixture. The previously prepared first mixture was added dropwise to the mixture to prepare a second mixture. After the second mixture was stirred at room temperature for 8 hours, distilled water (30 mL) was added thereto to terminate the reaction. An extraction process was performed on the second mixture by using an extraction funnel, distilled water, and dichloromethane (50 mL). After removing moisture from the organic layer obtained from the extraction process which was performed three times by using anhydrous MgSO₄, the organic solvent was removed by using a rotary evaporator. Accordingly, the organic material thus obtained was separated through silica gel column chromatography (ethyl acetone:ethyl acetate=1:2), so as to obtain a yellow liquid product. The liquid product weighed 807.1 mg, and a yield thereof was analyzed to be 46%.

### Synthesis Example 5: Synthesis of Compound 5

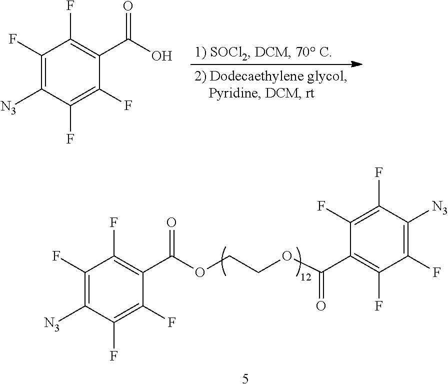

A dried magnetic bar placed in a 50 ml round-bottom flask was prepared. After the round-bottom flask was vacuum-dried while heating with a torch, the flask was filled with argon. 4-azido-2,3,5,6-tetrafluorobenzoic acid (670.9 mg, 2.85 mmol) was added to the flask and vacuum-dried for 1 hour. Thionyl chloride (SOCl₂) (0.23 mL, 3.29 mmol) and anhydrous DCM (7 mL) were sequentially added to the flask to prepare a mixture. The mixture was heated to 70 ° C. and stirred for 18 hours. After the mixture was cooled to room temperature, the organic solvent was removed therefrom by using a rotary evaporator, and then, additionally dried by using a vacuum pump to obtain a product. The product was diluted with anhydrous DCM (9 mL) to prepare a first mixture, which was prepared under an argon atmosphere.

A dried magnetic bar placed in a separate 100 ml round-bottom flask was prepared. After the round-bottom flask was vacuum-dried while heating with a torch, the flask was filled with argon. Dodecaethylene glycol (631.6 mg, 1.10 mmol), pyridine (260.5 mg, 3.29 mmol), and anhydrous DCM (30 mL) were added to the flask and stirred to prepare a mixture. The previously prepared first mixture was added dropwise to the mixture to prepare a second mixture. After the second mixture was stirred at room temperature for 8 hours, distilled water (20 mL) was added thereto to terminate the reaction. An extraction process was performed on the second mixture by using an extraction funnel, distilled water, and dichloromethane (50 mL). After removing moisture from the organic layer obtained from the extraction process which was performed three times by using anhydrous MgSO₄, the organic solvent was removed by using a rotary evaporator. Accordingly, the organic material thus obtained was separated through silica gel column chromatography (ethyl acetone:ethyl acetate=5:1), so as to obtain a yellow liquid product. The liquid product weighed 986.2 mg, and a yield thereof was analyzed to be 92%.

Preparation of Solid Electrolytes of Examples 1 to 3

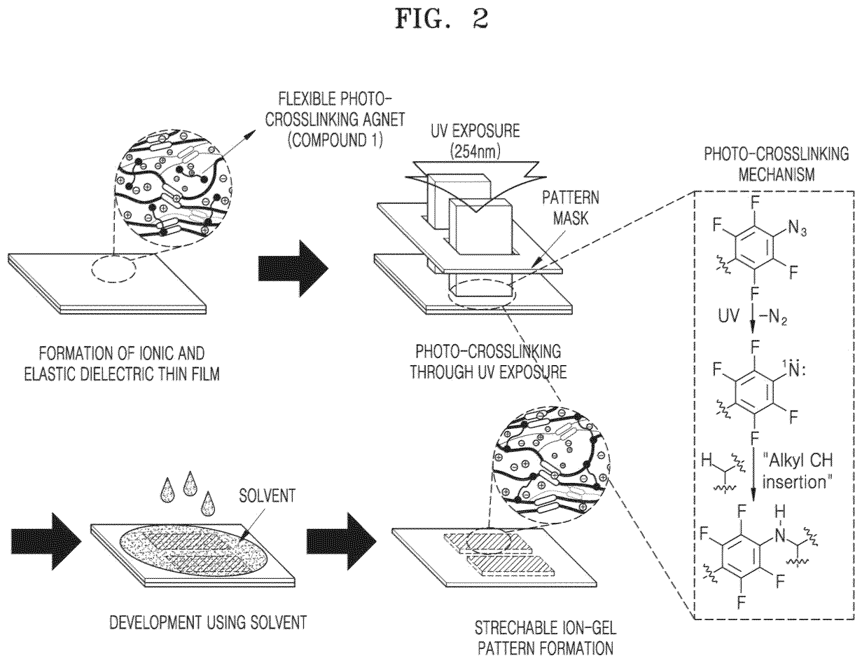

FIG. 2 is a view illustrating a preparation process of a solid electrolyte according to an embodiment of the present disclosure. Referring to FIG. 2, a preparation process of a solid electrolyte and a pattern formation process will be described.

A thermoplastic polyurethane (TPU) polymer including a repeating unit represented by Formula P1, dimethylformamide (DMF), and a ionic liquid ([EMIM][TFSI]) were mixed at a weight ratio shown in Table 1, and then stirred at 80° C. overnight (12 hours) at a speed of 120 rpm. Afterwards, Compound 1 as a photo-crosslinking agent was added to the mixture and stirred at 80° C. for 3 hours at a speed of 120 rpm, so as to prepare solid electrolytes of Examples 1 to 3.

The weight ratios of the TPU polymer, DMP, the ionic liquid, and the photo-crosslinking agent in Examples 1 to 3 are shown in Table 1 below.

A pattern mask was placed on the prepared solid electrolyte, and then exposed to ultraviolet (UV) rays (254 nm, 365 nm) at 45 mW/cm² for 600 seconds, and developed by using dimethylformamide (DMF) to prepare a solid electrolyte having an ion-gel pattern formed.

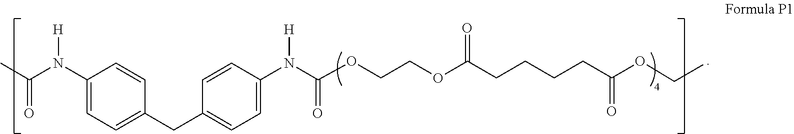

TABLE 1

| | | | | | Photo- |
|---|---|---|---|---|---|
| | | | | Ionic | crosslinking |
| | Photo- | TPU | DMF | liquid | agent |
| | crosslinking | (weight | (weight | (weight | (weight |
| | agent | ratio) | ratio) | ratio) | ratio) |
| Example 1 | Compound 1 | 1 | 8 | 4 | 0.01 |
| Example 2 | Compound 1 | 1 | 8 | 4 | 0.05 |
| Example 3 | Compound 1 | 1 | 8 | 4 | 0.1 |

Preparation of Solid Electrolytes of Comparative Examples 1 and 2

Except for using Compound A as a photo-crosslinking agent instead of the photo-crosslinking agent used in Examples 1 to 3, a TPU polymer, DMP, an ionic liquid, and a photo-crosslinking agent were mixed at a weight ratio shown in Table 2 in the same manner as described above, so as to prepare solid electrolytes of Comparative Examples 1 and 2.

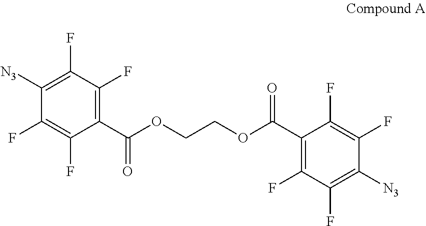 [SMILES: [N-]=[N+]=Nc1c(F)c(F)c(C(=O)OCCOC(=O)c2c(F)c(F)c(N=[N+]=[N-])c(F)c2F)c(F)c1F]

TABLE 2

| | | | | | Photo- |
|---|---|---|---|---|---|
| | | | | Ionic | crosslinking |
| | Photo- | TPU | DMF | liquid | agent |
| | crosslinking | (weight | (weight | (weight | (weight |
| | agent | ratio) | ratio) | ratio) | ratio) |
| Comparative | Compound A | 1 | 8 | 4 | 0.05 |
| Example 1 | | | | | |
| Comparative | Compound A | 1 | 8 | 4 | 0.1 |
| Example 2 | | | | | |

### Evaluation Example 1: Evaluation of Pattern Formation

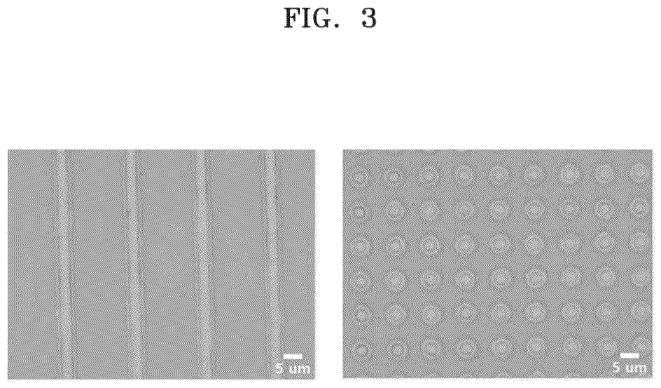

For the solid electrolyte prepared according to Example 1, an optical microscope (Olympus BX51) image confirming whether or not a pattern was formed is shown in FIG. 3.

Referring to FIG. 3(a), it was confirmed that a line pattern having a width of about 5 μm was formed, and referring to FIG. 3(b), it was confirmed that a dot pattern was formed.

That is, the solid electrolyte according to an embodiment was able to implement a high-resolution pattern by using photolithography.

### Evaluation Example 2: Evaluation of Ionic Conductivity

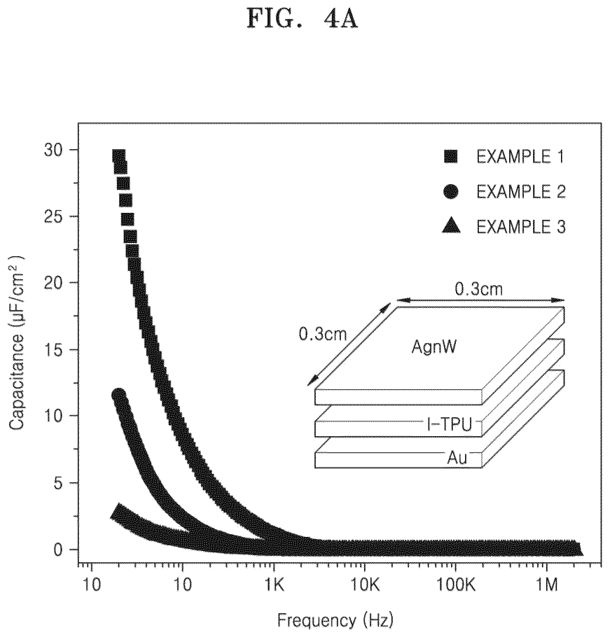

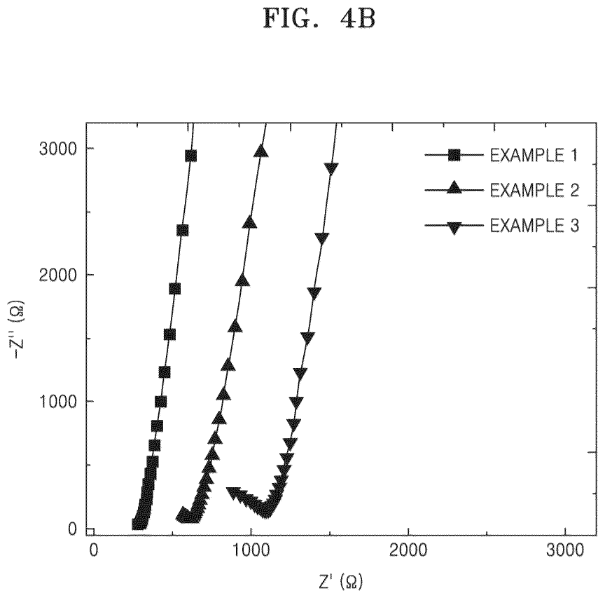

A capacitor device having a metal-insulator-metal (MIM) structure in which gold (Au) and silver nanowire (AgNW) were prepared as electrodes and the solid electrolyte (0.3 cm×0.3 cm) of each of Examples 1 to 3 was positioned between the electrodes was manufactured, and the electrochemical characteristics of the capacitor device were analyzed. As the analysis results, the capacitance and impedance are shown in FIGS. 4(a) and 4(b), respectively.

FIG. 4(a) shows a result of measuring the capacitance after the photo-patterning process of the solid electrolyte. Referring thereto, it was confirmed that high capacitance characteristics at the level of 30 μF/cm² were secured even after the pattern formation, referring that the electrochemical characteristics of the ion gel were not significantly reduced even after the photo-patterning process, and high capacitance characteristics were still secured. Accordingly, it was confirmed that the electrochemical characteristics and flexible mechanical characteristics of an ionic and elastic dielectric could be maintained even after the patterning process.

FIG. 4(b) shows a trade-off relationship in which the resistance of the electrolyte itself increases as the movement of ions in the solid electrolyte decreases according to the increase in the amount of the photo-crosslinking agent, and through the impedance analysis, the change in resistance according to the amount of the photo-crosslinking agent could be confirmed. In particular, Compound 1 has high compatibility with ions by including an ethylene oxide repeating unit, and thus it was confirmed that the trade-off relationship thereof was minimized compared to the case of using Compound A as the photo-crosslinking agent.

### Evaluation Example 3: Impedance Evaluation

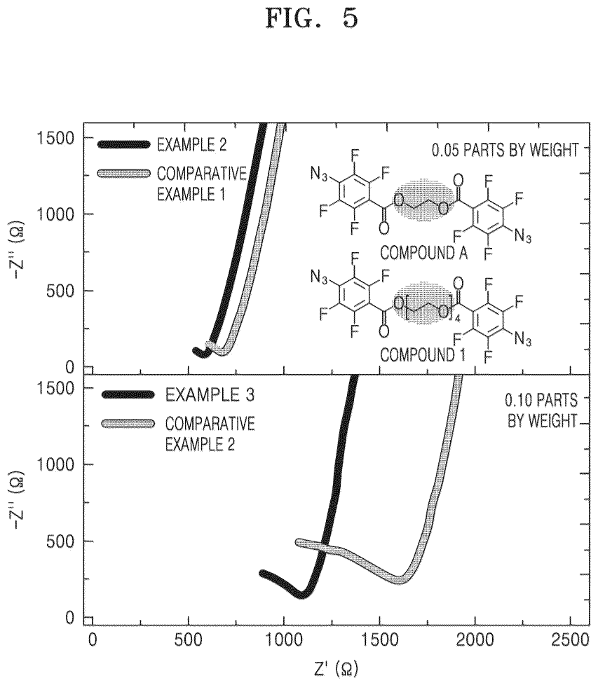

The impedance analysis was performed on the solid electrolytes of Examples 1 to 3 and Comparative Examples 1 and 2, and the results are shown in FIG. 5.

Referring to FIG. 5, when the crosslinkable compound according to an embodiment was used as the photo-crosslinking agent, an increase in the resistance of the electrolyte due to the crosslinking was confirmed to be suppressed, compared to the case where Compound A was used as the photo-crosslinking agent.

### Example 4: Manufacturing Example of Organic Thin-film Transistor

For use as a source electrode and a drain electrode, gold (Au) was used. After a semiconductor pattern was formed on a polymer semiconductor layer, the solid electrolyte of Example 2 was introduced as an insulator, and as a gate electrode, a silver nanowire (AgNW) was spray-coated, so as to manufacture an organic thin-film transistor. The semiconductor pattern on the polymer semiconductor layer was formed in the same manner as in the formation of the ion gel pattern in the Examples above, except that chloroform (CHCl₃) was used as a solvent in the development process.

The polymer semiconductor layer was formed by using a compound including a repeating unit represented by Formula S1 (5 mg/ml in chlorobenzene) and Compound B (2,2-bis(((4-azido-2,3,5,6-tetrafluorobenzoyl)oxy)methyl)propane-1,3-diyl bis(4-azido-2,3,5,6-tetrafluorobenzo-ate)) (1 wt %).

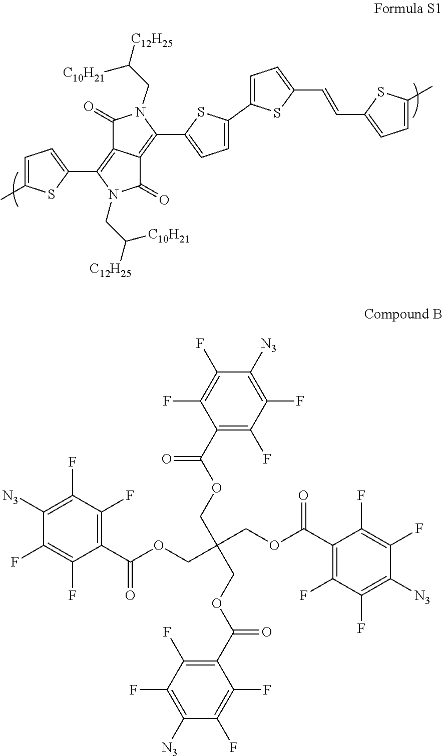

### Evaluation Example 4: Evaluation of Electrochemical Characteristics of Organic Thin-film Transistor

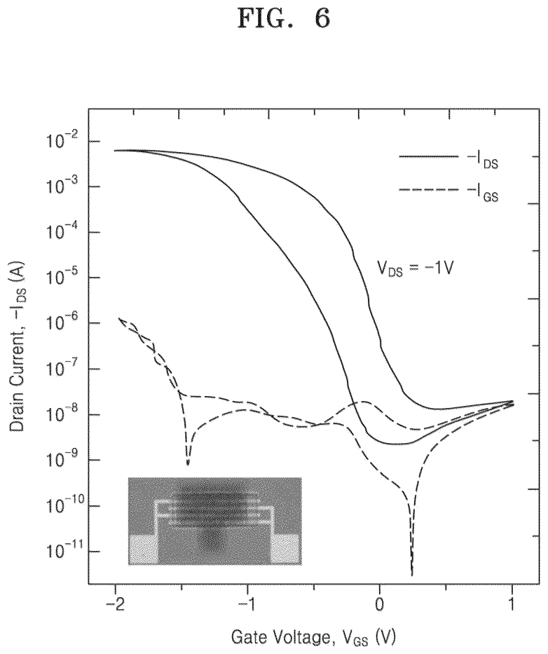

FIG. 6 shows the electrical characteristics of the organic thin-film transistor manufactured in Example 4, and the performance analysis results thereof of are summarized in Table 3.

TABLE 3

| | | Transistor of Example 4 | |
|---|---|---|---|
| Mobility | @20 Hz | 25.8 | (±0.74) |
| (cm²/V*s) | @50 Hz | 41.3 | (±1.24) |
| | @100 Hz | 70.5 | (±2.11) |
| V_{Th} (V) | | −0.746 | (±0.012) |

| | |
|---|---|
| On/Off ratio | up to 1.7 × 10⁶ |

Referring to FIG. 6 and Table 3, the organic thin-film transistor including the solid electrolyte as an insulator according to an embodiment was able to secure not only high charge mobility of 25.8 cm²/V·s in a low voltage region of −2 V, but also excellent on-off ratio characteristics of 1.7×10⁶. Accordingly, it was confirmed that the solid electrolyte according to an embodiment can be applied to a high-performance ‘skin-like’ electronic element requiring high elasticity, low power consumption, and high degree of integration at the same time. Meanwhile, the embodiments disclosed in the present specification and drawings are only presented as specific exampled to help understanding, and are not intended to limit the scope of the present disclosure. In addition to the embodiments disclosed herein, it is obvious to those skilled in the art that other modifications based on the technical idea of the present disclosure can be implemented.

### EXPLANATION OF REFERENCE NUMERALS DESIGNATING THE MAJOR ELEMENTS OF THE DRAWINGS

1. A crosslinkable compound represented by Formula 1: 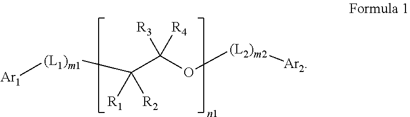
wherein, in Formula 1,
L₁ and L₂ are each independently a single bond, —C═O—, —C, a substituted or unsubstituted C₁-C₃₀ alkylene group, a substituted or unsubstituted C₂-C₃₀ alkenylene group, or a substituted or unsubstituted C₂-C₃₀ alkynylene group,
m1 and m2 are each independently 0, 1, 2, or 3,
Ar₁ and Ar₂ are each independently a substituted or unsubstituted C₅-C₆₀ carbocyclic group or a substituted or unsubstituted C₁-C₆₀ heterocyclic group,
Ar₁ and Ar₂ are each independently substituted with at least one crosslinkable group,
n1 is an integer from 2 to 300,000,
R₁ to R₄ are each independently hydrogen, deuterium, —F, —Cl, —Br, —I, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, —Si(Q₁)(Q₂)(Q₃), a substituted or unsubstituted C₅-C₆₀ carbocyclic group, or a substituted or unsubstituted C₁-C₆₀ heterocyclic group,
at least one of the substituted C₁-C₃₀ alkylene group, the substituted C₂-C₃₀ alkenylene group, the substituted C₂-C₃₀ alkynylene group, the substituted C₅-C₆₀ carbocyclic group, the substituted C₁-C₆₀ heterocyclic group, the substituted C₁-C₃₀ alkyl group, the substituted C₂-C₃₀ alkenyl group, the substituted C₂-C₃₀ alkynyl group, the substituted C₁-C₃₀ alkoxy group, and the substituted C₁-C₃₀ alkylthio group is substituted with deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃o alkoxy group, a C₁-C₃₀ alkylthio group, or —Si(Q₁)(Q₂)(Q₃), and
Q₁₁ to Q₁₃ are each independently hydrogen, deuterium, —F, —Cl, —Br, —I, a hydroxyl group, a cyano group, a C₁-C₃₀ alkyl group, a C₂-C₃₀ alkenyl group, a C₂-C₃₀ alkynyl group, a C₁-C₃o alkoxy group, or a C₁-C₃₀ alkylthio group.

2. The crosslinkable compound of claim 1, wherein the crosslinkable group contains an azide group (—N₃), a sulfur-containing group, or an unsaturated double bond-containing group.

3. The crosslinkable compound of claim 1, wherein the crosslinkable compound is represented by Formula 2: 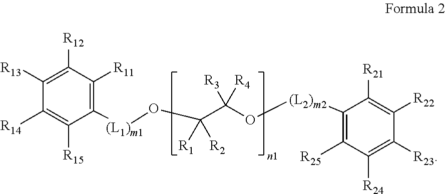
wherein, in Formula 2,
L₁, L₂, m1, m2, n1, and R₁ to R₄ are as defined in claim 1,
R₁₁ to R₁₅ and R₂₁ to R₂₅ are each independently a crosslinkable group, hydrogen, deuterium, —F, —Cl, —Br, —I, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, —Si(Q₁)(Q₂)(Q₃), a substituted or unsubstituted C₅-C₆o carbocyclic group, or a substituted or unsubstituted C₁-C₆₀ heterocyclic group,
at least one of R₁₁ to R₁₅ is a crosslinkable group, and
at least one of R₂₁ to R₂₅ is a crosslinkable group.

4. The crosslinkable compound of claim 3, wherein
one of R₁₁ to R₁₅ is an azide group, and the others are each —F or —Cl, and
one of R₂₁ to R₂₅ is an azide group, and the others are each —F or —Cl.

5. The crosslinkable compound of claim 1, wherein the crosslinkable compound is selected from Compounds 1 to 5:

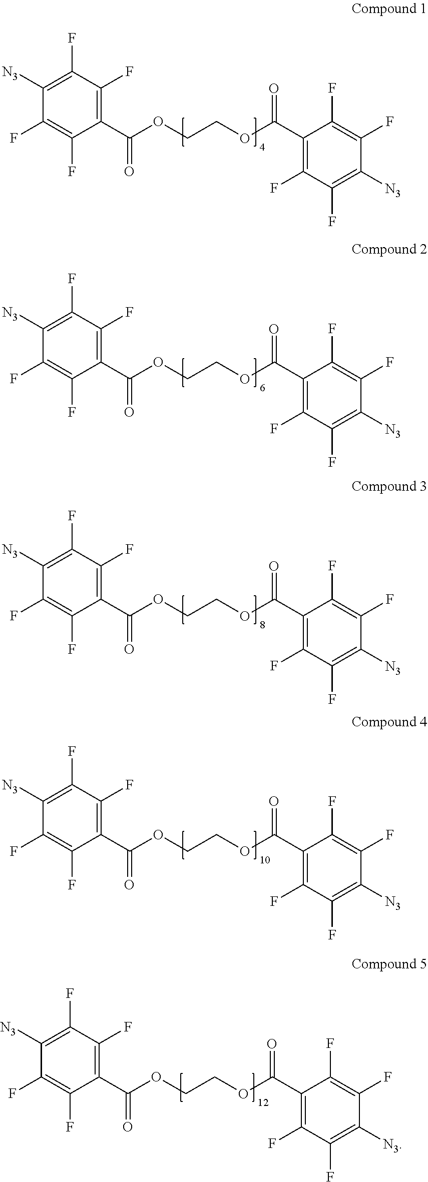

6. A composition for forming a solid electrolyte, comprising:
an ionic elastomer;
an ionic liquid; and
a photo-crosslinking agent,
wherein the photo-crosslinking agent contains the crosslinkable compound of claim 1.

7. The composition of claim 6, wherein the ionic elastomer is a thermoplastic polyurethane (TPU) polymer.

8. The composition of claim 7, wherein the TPU polymer contains a repeating unit represented by Formula 10: 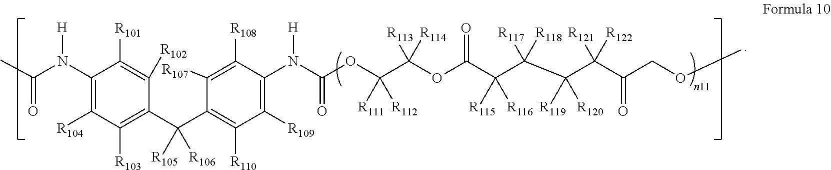
wherein, in Formula 10,
n11 is an integer from 1 to 5,000, and
R₁₀₁ to R₁₂₂ are each independently hydrogen, deuterium, —F, —Cl, —Br, —I, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, —Si(Q₁)(Q₂)(Q₃), a substituted or unsubstituted C₅-C₆₀ carbocyclic group, or a substituted or unsubstituted C₁-C₆₀ heterocyclic group.

9. The composition of claim 6, wherein the ionic liquid is a nitrogen-containing ionic liquid, a phosphorus (P)-containing ionic liquid, or any combination thereof.

10. The composition of claim 6, wherein
the ionic liquid contains a cation and an anion,
the cation is an ammonium ion, an imidazolium ion, a piperidinium ion, a pyrrolidinium ion, a phosphonium ion, or any combination thereof, and
the anion is a halogen ion, an acetate ion, a nitrate ion (NO₃⁻), a tetrafluoroborate ion (BF₄⁻), a hexafluorophosphate ion (PF₆⁻), a trifluoromethane sulfonate ion (Tf⁻), a bis((trifluoromethyl)sulfonyl)imide ion (TFSI⁻), or any combination thereof

11. The composition of claim 6, wherein a weight ratio of the photo-crosslinking agent to the ionic elastomer is 1:0.01 to 1:0.1.

12. A method of preparing a solid electrolyte, the method comprising exposing the composition of claim 6 to ultraviolet (UV) rays.

13. The method of claim 12, further comprising forming a pattern by developing the UV-exposed composition for forming a solid electrolyte.

14. A solid electrolyte prepared by using the composition of claim 6.

15. The solid electrolyte of claim 14, wherein the solid electrolyte is stretchable.

16. An electronic element comprising the solid electrolyte of claim 15.

17. The electronic element of claim 16, wherein the electronic element is any one of an organic solar cell (OSC), an organic thin-film transistor (OTFT), an organic light-emitting diode (OLED), an organic photodiode sensor (OPD), a perovskite solar cell, a perovskite light-emitting diode, and a thermoelectric device.
